(19) United States
(12) Patent Application Publication
(10) Pub. No.: US 2022/0365449 A1
(43) Pub. Date: Nov. 17, 2022

(54) METHOD FOR DETERMINING A REGISTRATION ERROR

(71) Applicant: Carl Zeiss SMT GmbH, Oberkochen (DE)

(72) Inventor: Mario Laengle, Jena (DE)

(21) Appl. No.: 17/742,733

(22) Filed: May 12, 2022

(30) Foreign Application Priority Data
May 14, 2021 (DE) 102021112547.2

(51) Int. Cl. G03F 7/20; G03F 9/00; G03F 1/72; G06T 7/11; G06T 7/00

(52) U.S. Cl. CPC G03F 7/70633; G03F 9/7003; G03F 9/7088; G03F 1/72; G06T 7/11; G06T 7/0004; G06T 2207/20116; G06T 2207/10

(57) ABSTRACT

The invention relates to a method for determining a registration error of a structure on a mask for semiconductor lithography, comprising the following method steps: generating an image of at least one region of the mask, determining at least one measuring contour in the image, and matching the forms of a design contour and a measuring contour to one another while at the same time matching the registration of the two contours.

### CROSS-REFERENCE TO RELATED APPLICATIONS

The present application claims priority from German patent application DE 10 2021 112 547.2, filed on May 14, 2021, the content of which is incorporated herein in full by reference.

### TECHNICAL FIELD

The invention relates to a method for determining a registration error of a mask for semiconductor lithography.

### BACKGROUND

Photolithographic masks are used in lithography systems or for producing microstructured components, such as integrated circuits or LCDs (liquid crystal displays). In a lithography process or a microlithography process, an illumination unit illuminates a photolithographic mask, which is also referred to as a photomask or simply a mask. The light passing through the mask or the light reflected by the mask is projected, by use of a projection optical element, onto a substrate (for example a wafer), which is coated with a light-sensitive layer (photoresist) and arranged in the image plane of the projection optical element, in order to transfer the structure elements of the mask onto the light-sensitive coating of the substrate and thus to produce a desired structure on the substrate.

The placement of structure elements on the surface of masks must be highly accurate, and so the permissible deviation from their specified positions—known as the registration error—preferably lies in the subnanometer range, in order not to lead to errors on wafers during exposure with the corresponding mask. The production of photomasks which can meet these requirements is extremely complex, susceptible to errors and hence expensive.

For determining the registration error, mask inspection microscopes, electron microscopes or position determining devices are used. The structures are usually detected on the basis of edge detection. For characterizing the structures, usually three methods are used.

The threshold method, in which the position of the structure is determined by determining a point of intersection of the edge, found on the basis of an intensity threshold value, and a measuring plane or reference plane, which extends perpendicularly to the structure.

The correlation method, in which the position of the structure is determined by a correlation of the aerial image captured by the position determining device and a simulated aerial image. The form of the structure captured in an aerial image by the position determining device and the form of the simulated structure are adapted to one another and the distance between the two structures is determined in a second step. This distance corresponds to the deviation of the structure captured by the aerial image from the target position.

The symmetry-correlation method, which is described in detail in German patent application DE 10 2010 047 051 A1.

These methods have the disadvantage that an unknown rotation of the structures to be captured in the image field can lead to falsified results in the case of the first two methods. Furthermore, errors in the image intensity away from the structures to be captured, which are actually irrelevant, are significant in the case of the last two methods, and can consequently lead to falsified measurement results.

### SUMMARY

An aspect of the present invention is to provide an improved method which overcomes the disadvantages of the prior art described above.

This aspect is achieved by a method with the features of the independent claim. The dependent claims relate to advantageous developments and variants of the invention.

A method according to the invention for determining a registration error of a structure on a mask for semiconductor lithography comprises the following method steps:
generating an image of at least one region of the mask,
determining at least one measuring contour in the image,
matching the forms of a design contour and a measuring contour to one another while at the same time matching the registration of the two contours.

In other words, the form and registration are adapted in such a way that a minimal mean lateral distance between the measuring contour and the design contour is achieved.

The measuring contours are contours that have been extracted from the image. The design contours are understood as meaning the contours such as are made available for example in a mask writer for producing or creating the structures on a mask. According to the invention, the form and registration of structures are advantageously optimized or matched at one and the same time.

The registration can in particular be minimized by minimizing the mean lateral distances of the two contours in the mask plane. Therefore, there is no correlation on the basis of intensity values, but instead lateral distances between the measurement and the design are considered. The advantage of this variant is in particular that errors which originate from a rotation of the measuring image with respect to the design image can be reliably detected and taken into account, and so a rotation does not impair the determined registration error with regard to the accuracy of the determination. In principle, it is also conceivable to optimize the form and position of the structures at one and the same time, but instead of the lateral distances also to use the intensities as an optimization criterion; similarly, the form and position could also be optimized or matched sequentially and the lateral distances used as the optimization criterion.

The matching of the forms of the contours can be brought about by a modification of the design contour; similarly, the matching of the forms of the contours can be brought about by a modification of the measuring contour or by a combination of the two methods.

In an advantageous variant of the invention, differences in the superposing of the measuring contour and the design contour can be used as a measure of the quality of the matching. These differences are also referred to as residues. The residues are to be minimized as much as possible and may in particular be a result of a) the shortest distances of all the measuring contour points in relation to the design contour line or b) the shortest distances of all the design contour points in relation to the measuring contour line or c) the total amount from a) and b). Therefore, instead of intensity differences as known in the prior art, lateral distances are considered. In principle, many methods of optimization are conceivable. Thus, for example, a multidimensional Newton method can be used for minimizing the distances between the measuring contour and the design contour. Such methods are comparatively robust and determine the optimum parameters for matching the form and registration by using the method of least squares.

In an advantageous embodiment of the invention, the mean value of all the distances between the measuring contour and the design contour can be used as a measure of the progress made in optimization. This numerical value, also referred to as MeanResid, represents a good measure of the progress made in the iterations during the matching. As soon as this value stagnates below a previously fixed maximum value between two iterations, the optimization can be ended.

The matching can also be performed for individual subregions of the image. In this case, separate parameters for individual image regions through to separate parameters for individual substructures, known as features, can be adapted in particular. Mixed forms are also conceivable, for example mixtures of global and local modification of the registration and/or mixtures of global and local modification of the form.

It can similarly be of advantage not to use certain regions of the image for the matching. Regions in which defects have been detected come into consideration for this purpose in particular.

Furthermore, an alternating, therefore changing, modification of the forms and the registration can be performed.

### BRIEF DESCRIPTION OF DRAWINGS

Exemplary embodiments and variants of the invention are explained in more detail below on the basis of the drawing, in which:

FIG. 1 shows an exemplary representation of the initial situation,

FIG. 2 shows the exemplary development of parameters used for the matching,

FIG. 3 shows the result of the matching, and

FIG. 4 shows the result of the matching with a defective structure.

### DETAILED DESCRIPTION

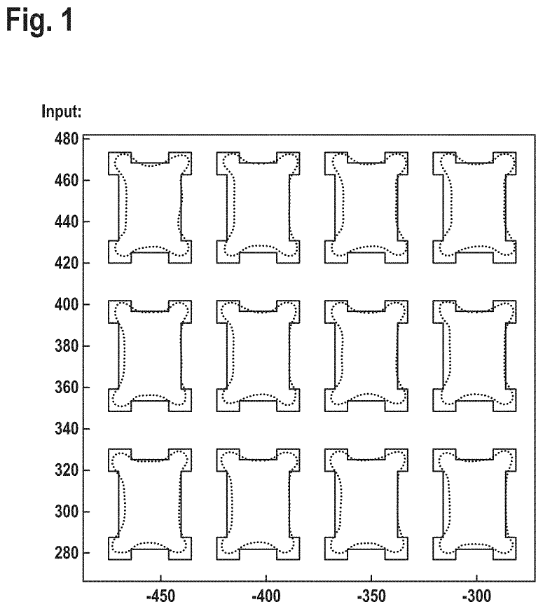

FIG. 1 shows an exemplary representation of the initial situation. The design contours are presented here by solid lines. The measuring contours are represented in FIG. 1 by dotted lines. The imaging used as a basis can be in particular an electron micrograph. The slight offset between the contours and a considerable deviation in the form of the contours themselves from one another can be seen well in FIG. 1. The aim in the evaluation of the example shown in FIG. 1 is therefore essentially that of determining the registration error, that is to say the offset of the measured contours with respect to the mask design. As already mentioned, one of the factors on which the accuracy in the determination of the registration error depends is the extent to which the measuring contour and the design contour deviate from one another. It is therefore important in the determination of the registration error to achieve matching between the design contour and the measuring contour that is as good as possible.

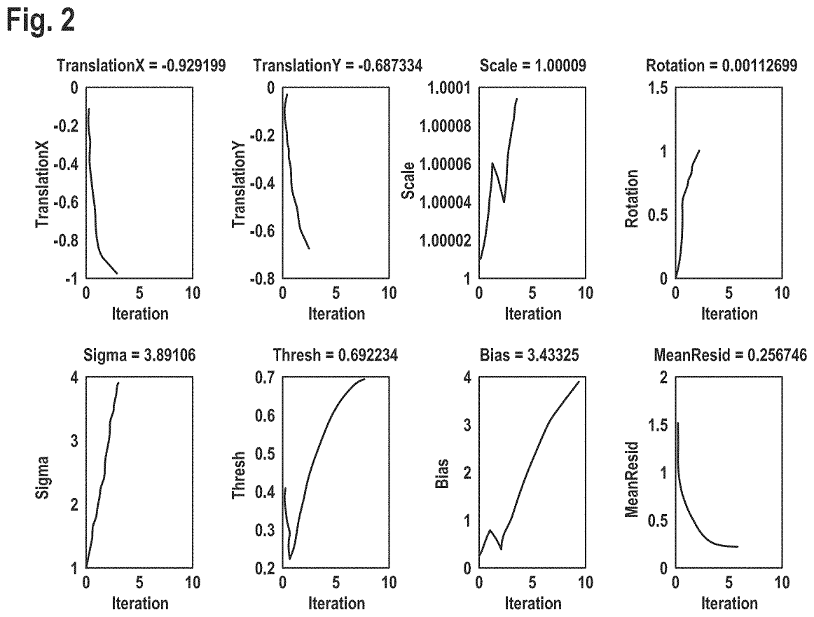

FIG. 2 shows the exemplary development of the parameters used for the matching of the forms and the mean lateral distances over 8 iteration steps. In this case, the upper 4 graphs represent parameters for the registration, known as registration parameters, whereas the graphs of the lower row, with the exception of the graph on the right, represent what are known as form parameters.

Specifically:

Registration Parameters:

1. TranslationX: Displacement of the contours in the x direction (0th order)

2. TranslationY: Displacement of the contours in the y direction (0th order)

3. Scale: How the contour extends to scale about an origin (1st order)

4. Rotation: Rotation of the contour about an origin (1st order) Other conceivable parameters for the optimization of the matching are the asymmetric scale and the asymmetric rotation, which are not used however in the example shown. Furthermore, the parameters of the first order can also be converted into ScaleX, ScaleY, Rotation X and Rotation Y.

In the example shown, the registration parameters mentioned were applied to the measuring contour. It is also conceivable to apply the registration parameters to the design contour; furthermore, combined application to the measuring contour and the design contour is also conceivable, but in the case of this variant it should be ensured that there are no undesired redundancies, and consequently an unwanted dependence of the parameters.

The form parameters (first 3 graphs of the lower row) serve for changing the form of the contours in order to match the appearance of the measuring contour and the design contour. For the variant shown, the form parameters described below were used (other form parameters are also conceivable):

1. Sigma is the width of a Gaussian filter by means of which an object created from the design contour is filtered.

2. Thresh is the function value of the Gaussian filtered object from which a new design contour is calculated.

3. Bias is the value by which the design contour newly calculated in 2. is displaced in the normal direction.

The form parameters can also be applied either to the measuring contour or to the design contour (as in the example shown), or else in a combined or divided manner.

The 4th graph of the lower row shows the optimization criterion already mentioned above, MeanResid. It can be seen well in the figure that, as from the 3rd iteration, the value for MeanResid begins to stagnate; in this case, the matching can be ended.

In principle, it should be ensured that the optimization parameters are chosen linearly independently of one another and produce an effect on the signal. For example, there is no sense in wanting to determine a translation in the X direction if the image only contains lines running in the X direction.

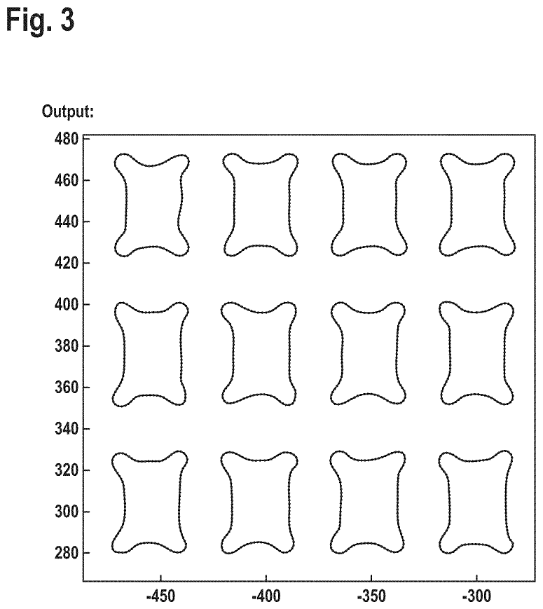

FIG. 3 shows the result of the matching. The much improved superposing of the measuring contour and the design contour when using the optimized form and registration parameters can be seen well.

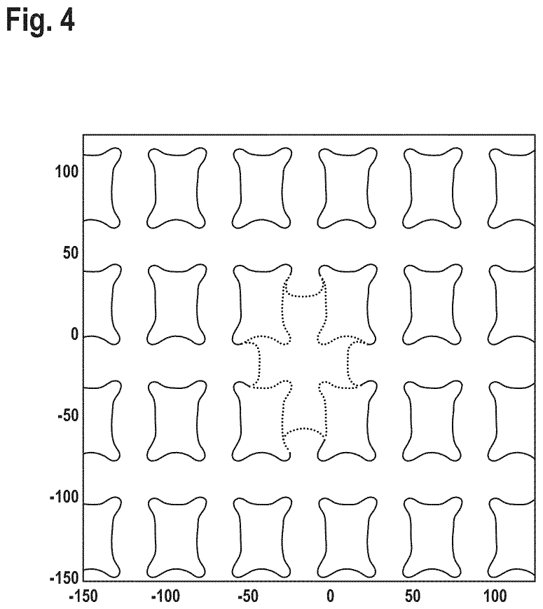

FIG. 4 shows the result of the matching with a defective structure; the area of the defect is represented in FIG. 4 by a dotted line. The considerable lateral deviation of the measured structure from the target structures can be seen well in FIG. 4. Such a defect would lead to considerable errors in the determination of the registration errors. It is therefore recommendable not to take regions with greatly deviating errors, as represented in the figure, into consideration in the matching.

In some examples, the determination of a registration error of a structure on a mask, the determination of at least one measuring contour in an image of at least one region of the mask, and the matching of the forms of a design contour and a measuring contour to one another while at the same time matching the registration of the two contours, and various computations and/or processing of data (e.g., image data and/or mask design data) described above can be implemented by one or more computers according to the principles described above. In some examples, the processing of data can be performed by one or more cloud computer servers. The one or more computers can include one or more data processors for processing data, one or more storage devices for storing data, such as one or more databases, and/or one or more computer programs including instructions that when executed by the one or more computers cause the one or more computers to carry out the processes. The computer can include one or more input devices, such as a keyboard, a mouse, a touchpad, and/or a voice command input module, and one or more output devices, such as a display, and/or an audio speaker. The computer can show graphical user interfaces on the display to assist the user.

In some implementations, the computer can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations by operating on input data and generating output. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

In some implementations, the operations associated with processing of data described in this document can be performed by one or more programmable processors executing one or more computer programs to perform the functions described in this document. A computer program can be written in any form of programming language, including compiled or interpreted languages, and it can be deployed in any form, including as a stand-alone program or as a module, component, subroutine, or other unit suitable for use in a computing environment.

For example, the computer can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as hard drives, magnetic disks, magneto-optical disks, or optical disks. Machine-readable storage media suitable for embodying computer program instructions and data include various forms of non-volatile storage area, including by way of example, semiconductor storage devices, e.g., EPROM, EEPROM, and flash storage devices; magnetic disks, e.g., internal hard disks or removable disks; magneto-optical disks; and CD-ROM and DVD-ROM discs.

In some implementations, the processing of data described above can be implemented using software for execution on one or more mobile computing devices, one or more local computing devices, and/or one or more remote computing devices. For instance, the software forms procedures in one or more computer programs that execute on one or more programmed or programmable computer systems, either in the mobile computing devices, local computing devices, or remote computing systems (which may be of various architectures such as distributed, client/server, or grid), each including at least one processor, at least one data storage system (including volatile and non-volatile memory and/or storage elements), at least one wired or wireless input device or port, and at least one wired or wireless output device or port.

In some implementations, the software may be provided on a medium, such as a CD-ROM, DVD-ROM, or Blu-ray disc, readable by a general or special purpose programmable computer or delivered (encoded in a propagated signal) over a network to the computer where it is executed. The functions may be performed on a special purpose computer, or using special-purpose hardware, such as coprocessors. The software may be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system may also be considered to be implemented as a computer-readable storage medium, configured with a computer program, where the storage medium so configured causes a computer system to operate in a specific and predefined manner to perform the functions described herein.

Certain features that are described in this specification in the context of separate embodiments can also be implemented in combination in a single embodiment. Conversely, various features that are described in the context of a single embodiment can also be implemented in multiple embodiments separately or in any suitable sub combination. The separation of various system components in the embodiments described above should not be understood as requiring such separation in all embodiments.

What is claimed is:

1. A method for determining a registration error of a structure on a mask for semiconductor lithography, comprising the following method steps:
generating an image of at least one region of the mask,
determining at least one measuring contour in the image, and
matching the forms of a design contour and a measuring contour to one another while at the same time matching the registration of the two contours.

2. The method of claim 1,
wherein the registration is matched by minimizing the mean lateral distances of the two contours in the image plane.

3. The method of claim 1,
wherein the matching of the forms and registration of the contours is brought about by a modification of the design contour.

4. The method of claim 1,
wherein the matching of the forms and registration of the contours is brought about by a modification of the measuring contour.

5. The method of claim 1,
wherein lateral distances between the measuring contour and the design contour are used as a measure of the quality of the matching.

6. The method of claim 5,
wherein a method of optimization, in particular a multidimensional Newton method, is used for minimizing the lateral distances.

7. The method of claim 5,
wherein the mean value of all the lateral distances is used as a measure of the progress made in the optimization.

8. The method of claim 1,
wherein the matching is performed separately for individual subregions of the image.

9. The method of claim 1,
wherein certain regions of the image are not used for the matching.

10. The method of claim 9,
wherein the regions that are not used for the matching are regions in which defects have been detected.

11. The method of claim 1,
wherein an alternating modification of the forms and the mean lateral distances is performed.

12. The method of claim 2,
wherein the matching of the forms and registration of the contours is brought about by a modification of the design contour.

13. The method of claim 2,
wherein the matching of the forms and registration of the contours is brought about by a modification of the measuring contour.

14. The method of claim 2,
wherein lateral distances between the measuring contour and the design contour are used as a measure of the quality of the matching.

15. The method of claim 2,
wherein the matching is performed separately for individual subregions of the image.

16. The method of claim 2,
wherein certain regions of the image are not used for the matching.

17. The method of claim 2,
wherein an alternating modification of the forms and the mean lateral distances is performed.

18. The method of claim 3,
wherein the matching of the forms and registration of the contours is brought about by a modification of the measuring contour.

19. The method of claim 3,
wherein lateral distances between the measuring contour and the design contour are used as a measure of the quality of the matching.

20. The method of claim 3,
wherein the matching is performed separately for individual subregions of the image.
